(19) United States
(12) Patent Application Publication
(10) Pub. No.: US 2025/0210600 A1
(43) Pub. Date: Jun. 26, 2025

(54) SYSTEM-ON-CHIP GAP FILL METHOD AND STRUCTURE

(71) Applicant: Advanced Micro Devices, Inc., Santa Clara, CA (US)

(72) Inventor: Hsiang-Wei Liu, Hsinchu City (TW)

(73) Assignee: Advanced Micro Devices, Inc., Santa Clara, CA (US)

(21) Appl. No.: 18/394,719

(22) Filed: Dec. 22, 2023

(51) Int. Cl. H01L 25/10; H01L 21/56; H01L 23/29; H01L 23/31; H01L 25/00

(52) U.S. Cl. CPC H01L 25/105; H01L 21/568; H01L 23/3121; H01L 23/3185; H01L 23/3192; H01L 25/50; H01L 23/291

(57) ABSTRACT

A system-on-chip structure includes a substrate, first and second die disposed over a surface of the substrate and separated by an inter-die gap, a protection layer disposed over a sidewall of each of the first and second die, and a gap fill layer disposed over the protection layers and substantially filling the inter-die gap.

### BACKGROUND

System-on-chip (SoC) architectures can be used to integrate multiple electronic components into a single semiconductor device. Example SoC components include a processor core, graphics processor, memory, input/output interfaces, and the like. System-on-chip structures are typically formed on a semiconductor substrate using metal-oxide-semiconductor (MOS) technology and then singulated using a dicing operation to form individual chips or “die” that can be picked and packaged.

### BRIEF DESCRIPTION OF THE DRAWINGS

The accompanying drawings illustrate a number of exemplary implementations and are a part of the specification. Together with the following description, these drawings demonstrate and explain various principles of the present disclosure.

FIG. 1 illustrates the existence of defects proximate to a scribe line between neighboring die according to some implementations.

FIG. 2 is a series of schematic illustrations of an example process flow for eliminating the formation of defects along an inter-die scribe line according to various implementations.

FIG. 3 is a flowchart of an example method for fabricating a system-on-chip architecture in accordance with certain implementations.

Throughout the drawings, identical reference characters and descriptions indicate similar, but not necessarily identical, elements. While the examples described herein are susceptible to various modifications and alternative forms, specific implementations have been shown by way of example in the drawings and will be described in detail herein. However, the example implementations described herein are not intended to be limited to the particular forms disclosed. Rather, the present disclosure covers all modifications, equivalents, and alternatives falling within the scope of the appended claims.

### DETAILED DESCRIPTION OF EXAMPLE IMPLEMENTATIONS

The present disclosure is generally directed to wafer dicing and more particularly to the processing of a semiconductor wafer to mitigate the creation of defects between adjacent die prior to or during dicing operations.

During formation or processing of a semiconductor wafer, individual integrated circuits (e.g., chips) are laterally offset from one another. The gap between adjacent chips may be referred to as a “dicing street” or “scribe line” along which the wafer can be cut to create a plurality of individual chips. A gap dielectric can be formed along the scribe line between neighboring chips to fill the space therebetween.

In accordance with some implementations, a protection layer can be formed over the chip sidewalls prior to forming the gap dielectric. The protection layer can itself be a defect free or a substantially defect free conformal layer that is configured to prevent the creation and propagation of cracks or other defects that can otherwise negatively impact the reliability and performance of the die and associated integrated circuits. In some instantiations, the protection layer can improve adhesion between the gap dielectric and a chip sidewall. The protection layer may be a high density layer. For instance, the density of the protection layer can be greater than the density of the gap dielectric.

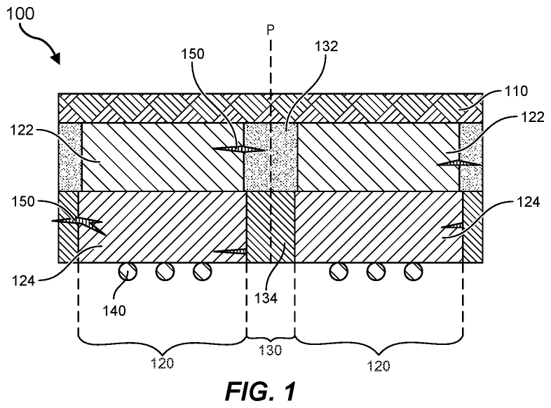

The following will provide, with reference to FIGS. 1-3, detailed descriptions of SoC architectures having a protection layer formed over the sidewalls of adjacent die as well as related methods of manufacture.

Referring to FIG. 1, in a comparative stacked SoC architecture 100, a carrier substrate 110 supports a plurality of stacked die 120 separated by a scribe line P. Each stacked die 120 can include a top die 122 and a bottom die 124 although further stacked or unstacked architectures are contemplated. In the illustrated example, top die 122 are located adjacent to the carrier substrate 110 and bottom die 124 are located over each respective top die 122. Within each inter-die gap 130, a gap fill layer is disposed over the carrier substrate 110 between adjacent stacked die 120 and can include a top gap dielectric 132 between neighboring top die 122 and a bottom gap dielectric 134 between neighboring bottom die 124.

The top and bottom gap dielectric layers 132, 134 can include any suitable dielectric material, such as silicon dioxide or silicon nitride, and can be formed using chemical vapor deposition (CVD), for example. The gap fill layers can be configured to fill the volume proximate to scribe line P between neighboring die.

Solder bumps 140 are formed over the bottom surface of each bottom die 124. The plurality of solder bumps 140 can be configured to form electrical interconnects with each stacked die 120 during downstream integration.

As shown, gap fill crack defects 150 can form at the interface between the gap fill layer and the adjacent die. Such cracks can undesirably propagate into the die, which can cause failure and disrupt performance.

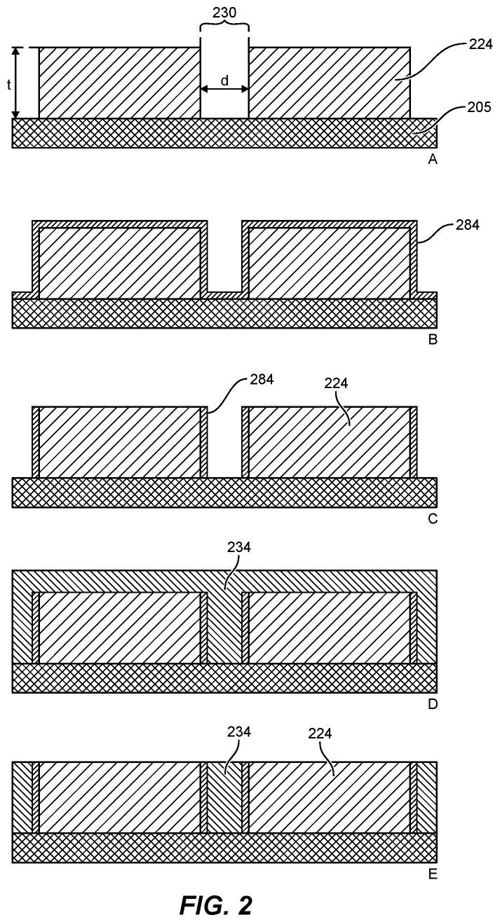

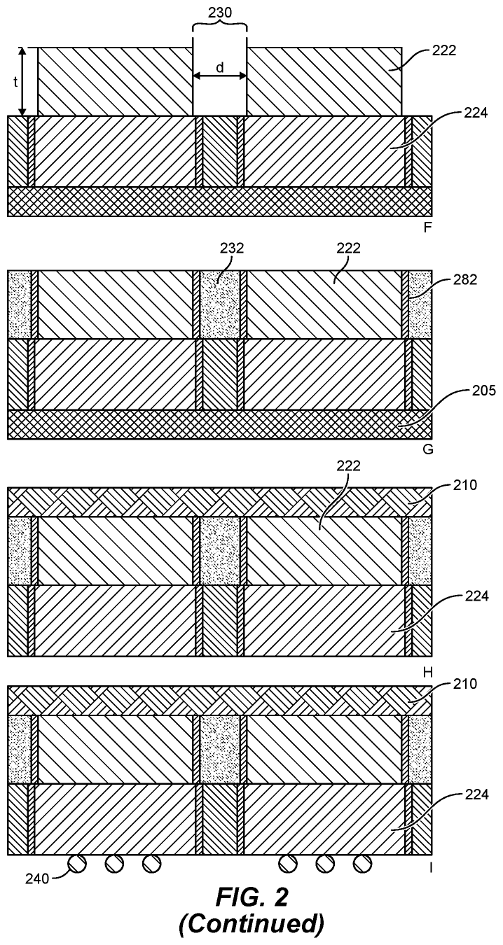

Turning to FIG. 2, shown schematically is a process for forming a protection layer over die sidewalls within an SoC architecture. In accordance with various implementations, the protection layer is configured to mitigate crack formation at die sidewall surfaces and/or prevent crack propagation into a die. The protection layer can be formed as a conformal layer, i.e., having uniform thickness, and can include any suitable dielectric material, such as silicon dioxide, silicon nitride, titanium oxide, aluminum oxide, etc. An exemplary method of forming the protection layer includes atomic layer deposition (ALD). The protection layer can include one or more amorphous and/or crystalline phases.

Referring to FIG. 2A, individual die 224 (e.g., bottom die) can be formed over or placed over a substrate 205 defining an inter-die gap 230 therebetween. A thickness (t) of the bottom die 224 can range from approximately 10 micrometers to approximately 100 micrometers. In some implementations, a width (d) of the inter-die gap 230 between neighboring bottom die 224 can range from approximately 50 micrometers to approximately 300 micrometers, although lesser or greater inter-die spacings are contemplated.

As shown in FIG. 2B, a conformal protection layer 284 is formed over the structure of FIG. 2A, including over the top and sidewall surfaces of die 224. Protection layer 284 can be formed using any suitable conformal deposition process, such as atomic layer deposition, and can include any suitable dielectric material, such as silicon dioxide, silicon nitride, titanium oxide, aluminum oxide, etc. In some implementations, the protection layer 284 can include a single layer. In some implementations, the protection layer 284 can include a multi-layer. A thickness of the protection layer 284 can be substantially uniform and can range from approximately 0.1 micrometers to approximately 20 micrometers. For instance, a variability in the thickness of the protection layer can be approximately 5% or less.

The protection layer 284 can be selectively removed from horizontal surfaces using an anisotropic etch. An anisotropic etch can include a dry etching process such as reactive ion etching. As shown in FIG. 2C, selective removal of the protection layer can expose a top surface of the bottom die 224. Following the anisotropic etch, as depicted in the illustrated example, the protection layer 284 overlies the entirety each die sidewall. Alternatively, the etch back can remove the protection layer from upper portions of the die sidewalls such that the protection layer overlies only a portion of the sidewalls.

A gap fill material, such as silicon dioxide or silicon nitride, is deposited over the structure of FIG. 2C in an amount effective to fill the gap between adjacent die. That is, as shown in FIG. 2D, a layer 234 of gap fill material is deposited directly over the protection layer 284 and over top surfaces of adjacent die to completely fill the inter-die gap 230. A CVD process can be used to form the gap fill layer 234. Referring to FIG. 2E, the deposited gap fill layer 234 overlying the bottom die 224 can be removed, such as with chemical mechanical polishing (CMP), to again expose top surfaces of the bottom die 224. Chemical mechanical polishing (CMP) is a material removal process that uses both chemical reactions and mechanical forces to remove material and planarize a surface.

Referring to FIG. 2F, top die 222 are formed on or placed over the exposed top surfaces of bottom die 224. A width (d) of the inter-die gap 230 between top die 222 can range from approximately 50 micrometers to approximately 300 micrometers, although lesser or greater inter-die spacings are contemplated. A thickness (t) of the top die 222 can range from approximately 10 micrometers to approximately 100 micrometers. In accordance with some instantiations, the top and bottom die thicknesses can be equivalent or substantially equivalent. Referring to FIG. 2G, the process steps of FIGS. 2B-2E can be repeated with respect to top die 222. That is, the structure of FIG. 2G can be created by forming a protection layer 282 over top die 222, removing horizontal portions of the protection layer 282 to expose a top surface of top die 222, forming a gap fill layer 232 within unfilled portions of inter-die gap 230, and removing the gap fill layer 232 overburden to expose top surfaces of top die 222.

Referring to FIG. 2H, substrate 205 can be removed and the stacked architecture can be re-bonded to substrate 210. In the illustrated embodiment, bottom die 224 can be de-bonded from substrate 205 and new substrate 210 can be bonded to top die 222. Substrate 205 and substrate 210 may each include a carrier wafer. Prior to dicing, as shown in FIG. 2I, solder bumps 240 can be formed over the bottom surface of each bottom die 224. Solder bumps 240 can be configured to form electrical interconnects with each stacked die.

Protection layers 282, 284 can inhibit crack initiation and form a barrier to crack propagation within inter-die gap 230. Although the illustrated SoC architecture is described in FIG. 2 in connection with a two layer die stack, it will be appreciated that a single die layer or a greater number of stacked die layers can be used.

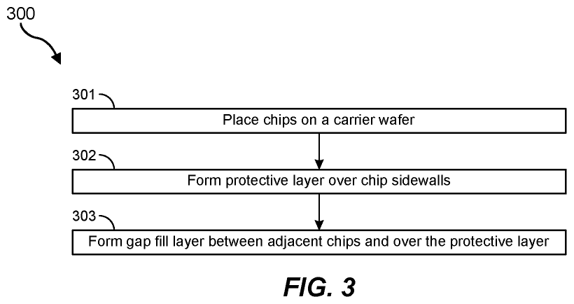

Referring to FIG. 3, depicted is a flowchart summarizing an example manufacturing method for forming a system-on-chip gap fill structure in accordance with various implementations. The illustrated method 300 includes forming a plurality of semiconductor chips at a prescribed inter-chip spacing over a carrier substrate (301), forming a protection layer over the chip sidewalls (302), and forming a gap fill layer within the inter-chip gap and over the protection layers (303).

A system-on-chip architecture includes a substrate, first and second die disposed over a surface of the substrate and separated by an inter-die gap, a protection layer disposed over a sidewall of each of the first and second die, and a gap fill layer disposed over the protection layers and substantially filling the inter-die gap. In some implementations, the first and second die can have a stacked structure and the first and second die thicknesses can be substantially equal. One or both die can include a processor. The die can be arranged on the substrate to have an inter-die spacing of from approximately 50 micrometers to approximately 300 micrometers.

The protection layers can include a dielectric material, such as silicon dioxide, silicon nitride, titanium oxide, and aluminum oxide, and can have a thickness ranging from approximately 0.1 micrometers to approximately 20 micrometers. The thickness variability of each protection layer can be less than approximately 5%. As disclosed herein, the protection layers are respectively configured to inhibit crack formation in the first and second die. The gap fill layer can include a dielectric material, such as silicon dioxide and silicon nitride.

A further system-on-chip structure can include a carrier substrate, a die disposed over a surface of the substrate, a protection layer disposed over a sidewall of the die, and a gap fill layer disposed over the protection layer and over a surface of the carrier substrate proximate to the die. In various implementations, a density of the protection layer can be greater than a density of the gap fill layer.

A method of manufacture includes positioning a semiconductor die on carrier wafer, forming a protection layer over a sidewall of the semiconductor die, and forming a gap fill layer over the carrier wafer adjacent to the semiconductor die and over the protection layer. A method of forming the protection layer includes atomic layer deposition.

The term “layer,” as used herein, can generally refer to an over-formed sheet or thickness of material. A layer may be compositionally or structurally distinct from the material above or below it. Examples of a layer include, without limitation, a protection layer disposed over a sidewall of a chip and a gap layer disposed between adjacent chips.

On a semiconductor wafer having a plurality of processed die, a protection layer is formed over die sidewalls. The protection layer can include any suitable dielectric material and is configured to inhibit the formation and propagation of gap fill cracks. The protection layer can have a substantially uniform thickness, for example. Additionally, the protection layer can enable die stacking architecture flexibility.

While the foregoing disclosure sets forth various implementations using specific block diagrams, flowcharts, and examples, each block diagram component, flowchart step, operation, and/or component described and/or illustrated herein can be implemented, individually and/or collectively, using a wide range of hardware, software, or firmware (or any combination thereof) configurations. In addition, any disclosure of components contained within other components should be considered example in nature since many other architectures can be implemented to achieve the same functionality.

The process parameters and sequence of steps described and/or illustrated herein are given by way of example only and can be varied as desired. For example, while the steps illustrated and/or described herein can be shown or discussed in a particular order, these steps do not necessarily need to be performed in the order illustrated or discussed. The various example methods described and/or illustrated herein can also omit one or more of the steps described or illustrated herein or include additional steps in addition to those disclosed.

While various implementations have been described and/or illustrated herein in the context of fully functional computing systems, one or more of these example implementations can be distributed as a program product in a variety of forms, regardless of the particular type of computer-readable media used to actually carry out the distribution. The implementations disclosed herein can also be implemented using modules that perform certain tasks. These modules can include script, batch, or other executable files that can be stored on a computer-readable storage medium or in a computing system. In some implementations, these modules can configure a computing system to perform one or more of the example implementations disclosed herein.

The preceding description has been provided to enable others skilled in the art to best utilize various aspects of the example implementations disclosed herein. This example description is not intended to be exhaustive or to be limited to any precise form disclosed. Many modifications and variations are possible without departing from the spirit and scope of the present disclosure. The implementations disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

What is claimed is:

1. A system-on-chip structure comprising:
a substrate;
first and second die disposed over a surface of the substrate and separated by an inter-die gap;
a protection layer disposed over a sidewall of each of the first and second die; and
a gap fill layer disposed over the protection layers and substantially filling the inter-die gap.

2. The system-on-chip structure of claim 1, wherein a thickness of the first and second die are substantially equal.

3. The system-on-chip structure of claim 1, wherein the first die comprises a top die and a bottom die and the second die comprises a top die and a bottom die.

4. The system-on-chip structure of claim 1, wherein the first and second die each comprise a processor.

5. The system-on-chip structure of claim 1, wherein a spacing between the first and second die ranges from approximately 50 micrometers to approximately 300 micrometers.

6. The system-on-chip structure of claim 1, wherein the protection layers comprise a dielectric material.

7. The system-on-chip structure of claim 1, wherein the protection layers comprise a dielectric material selected from the group consisting of silicon dioxide, silicon nitride, titanium oxide, and aluminum oxide.

8. The system-on-chip structure of claim 1, wherein a thickness of the protection layers range from approximately 0.1 micrometers to approximately 20 micrometers.

9. The system-on-chip structure of claim 8, wherein the protection layer thicknesses have a variability of less than approximately 5%.

10. The system-on-chip structure of claim 1, wherein the protection layers are configured to inhibit crack formation in the first and second die.

11. The system-on-chip structure of claim 1, wherein the gap fill layer comprises a dielectric material.

12. The system-on-chip structure of claim 1, wherein the gap fill layer comprises a dielectric material selected from the group consisting of silicon dioxide and silicon nitride.

13. A system-on-chip structure comprising:
a carrier substrate;
a die disposed over a surface of the substrate;
a protection layer disposed over a sidewall of the die; and
a gap fill layer disposed over the protection layer and over a surface of the carrier substrate proximate to the die.

14. The system-on-chip structure of claim 13, wherein the protection layer comprises a first dielectric material and the gap fill layer comprises a second dielectric material.

15. The system-on-chip structure of claim 13, wherein a density of the protection layer is greater than a density of the gap fill layer.

16. A method comprising:
positioning a semiconductor die on carrier wafer;
forming a protection layer over a sidewall of the semiconductor die; and
forming a gap fill layer over the carrier wafer adjacent to the semiconductor die and over the protection layer.

17. The method of claim 16, wherein forming the protection layer comprises atomic layer deposition.

18. The method of claim 16, wherein the protection layer comprises a dielectric material selected from the group consisting of silicon dioxide, silicon nitride, titanium oxide, and aluminum oxide.

19. The method of claim 16, wherein a thickness of the protection layer ranges from approximately 0.1 micrometers to approximately 20 micrometers.

20. The method of claim 19, wherein the protection layer thickness has a variability of less than approximately 5%.
